(19) United States
(12) Patent Application Publication
(10) Pub. No.: US 2023/0209781 A1
(43) Pub. Date: Jun. 29, 2023

(54) DISTRIBUTION AND MANAGEMENT COOLING SYSTEM FOR IMMERSION LIQUID COOLANT

(71) Applicant: Baidu USA LLC, Sunnyvale, CA (US)

(72) Inventor: Tianyi GAO, San Jose, CA (US)

(21) Appl. No.: 17/561,257

(22) Filed: Dec. 23, 2021

(51) Int. Cl. H05K 7/20

(52) U.S. Cl. CPC H05K 7/20836; H05K 7/20236; H05K 7/20781; H05K 7/20272

(57) ABSTRACT

According to one embodiment, a cooling system that includes one or more information technology (IT) enclosures, each IT enclosure having one or more pieces of IT equipment that is configured to provide IT serveries and is at least partially submerged within a liquid coolant, a distribution manifold to which each of the one or more IT enclosures is coupled in parallel to one another, and a management unit that is coupled to the distribution manifold and to a liquid coolant source that is arranged to supply liquid coolant to the management unit that stores the liquid coolant, the management unit is configured to maintain and automatically balancing a same level of liquid coolant in each of the one or more IT enclosures and the liquid coolant stored in the management unit via the distribution manifold.

### FIELD

Embodiments of the present disclosure relate generally to a cooling system for immersion cooled information technology (IT) equipment.

### BACKGROUND

Thermal management for a data center that includes several active electronics racks is critical to ensure proper performance of servers and other information technology (IT) equipment (e.g., performing IT data processing services) that is operating in the racks. Without proper thermal management, however, the thermal environment (e.g., temperature) within the racks may exceed thermal operational thresholds, which may result in adverse consequences (e.g., servers failing, etc.). One way to manage the thermal environment is the use of cooling air to cool the IT equipment. The cooling air is recirculated through cooling units. Heat generated by the IT equipment tis captured by the cooling air and is extracted by the cooling units. One common cooling unit is a computer room air conditioning (CRAC) unit that is a device that intakes hot exhaust region air and supplies cooling air to maintain a data center's thermal environment.

Recently, data centers have been deploying more high-power density electronics racks, where more high-density chips are packed closer together to provide more processing power. This is especially the case due to developments in artificial intelligence (AI) and cloud-based services, which require high performance and high-power density processors, such as control central processing units (CPUs) and graphic processing units (GPUs). Cooling these high-density racks by maintaining a proper thermal environment may be an issue with existing cooling systems, such as a CRAC unit. For instance, although the CRAC unit may maintain the thermal environment with more conventional (or lower-density) racks, the unit may be unable to effectively (and/or efficiently) cool high-power density racks because they may generate heat loads at a higher rate due to the higher density electronics. Another challenge for air cooling high-density racks is moving a large amount of airflow sufficient to cool the racks.

Immersion cooling, on the other hand, which involves at least partially submerging electronics in a dielectric solution (liquid) is a feasible solution for high-density electronics. Specifically, the electronics are placed within a coolant tank, which is then filled with the dielectric solution. Some existing immersion cooling solutions implement two-phase liquid cooling in which vapor produced when the dielectric solution is heated up, which is a result of heat transfer by the high-density electronics submerged therein, is condensed back into liquid form and returned to the coolant tank. Implementing two-phase immersion cooling, however, has challenges. For example, existing solutions segregate coolant tanks, such that the dielectric solution is only contained within the tanks. As a result, coolant levels within each individual tank must be manually monitored (e.g., by technicians) in order to ensure electronics are properly submerged. Such a solution is inefficient and may not be a proper solution for hyperscale deployment (e.g., with a significant number of coolant tanks used to cool high-density electronics). Thus, there is a need for a cooling system that provides an efficient architecture for managing and distributing two-phase immersion liquid coolant for different scales of immersion cooling deployment.

### BRIEF DESCRIPTION OF THE DRAWINGS

The embodiments are illustrated by way of example and not by way of limitation in the figures of the accompanying drawings in which like references indicate similar elements. It should be noted that references to “an” or “one” embodiment of this disclosure are not necessarily to the same embodiment, and they mean at least one. Also, in the interest of conciseness and reducing the total number of figures, a given figure may be used to illustrate the features of more than one embodiment, and not all elements in the figure may be required for a given embodiment.

FIG. 1 shows an example of a distribution and management cooling system that includes several information technology (IT) enclosures coupled to a management unit via a distribution manifold according to one embodiment.

FIG. 2 shows an example of the distribution and management cooling system that includes a discharging manifold according to one embodiment.

FIG. 3 shows an example of the distribution and management cooling system according to another embodiment.

FIG. 4 shows an IT cluster in a data center that includes an example of the distribution and management cooling system with several management units according one embodiment.

FIG. 5 shows the data center that includes another example of the distribution and management cooling system according to one embodiment.

FIG. 6 shows the data center that includes another example of the distribution and management cooling system according to another embodiment.

### DETAILED DESCRIPTION

Several embodiments of the disclosure with reference to the appended drawings are now explained. Whenever the shapes, relative positions and other embodiments of the parts described in a given embodiment are not explicitly defined, the scope of the disclosure here is not limited only to the parts shown, which are meant merely for the purpose of illustration. Also, while numerous details are set forth, it is understood that some embodiments may be practiced without these details. In other instances, well-known circuits, structures, and techniques have not been shown in detail so as not to obscure the understanding of this description. Furthermore, unless the meaning is clearly to the contrary, all ranges set forth herein are deemed to be inclusive of each range's endpoints.

Reference in the specification to “one embodiment” or “an embodiment” means that a particular feature, structure, or characteristic described in conjunction with the embodiment can be included in at least one embodiment of the disclosure. The appearances of the phrase “in one embodiment” in various places in the specification do not necessarily all refer to the same embodiment.

The present disclosure solves the problem of efficiently and effectively managing and distributing liquid coolant to immersion cooling information technology (IT) enclosures that have high-density IT equipment at least partially submerged within (two-phase) immersion liquid coolant. Specifically, the present disclosure describes a distribution and management cooling system in which individual IT enclosures are connected (e.g., in parallel with one another) to a management unit via a distribution manifold. The management unit maintains a (e.g., same) liquid coolant level throughout at least some of the IT enclosures by supplying liquid coolant through the distribution manifold. In particular, the management unit may include a reservoir that is coupled between the distribution manifold and a (e.g., data center) liquid coolant source, where liquid coolant within the IT enclosures that are connected to the reservoir has a same coolant level as the liquid coolant within the reservoir, which is due to the gravity and the pressure of the liquid coolant. Since the coolant level within the reservoir tracks the coolant levels in the IT enclosures (e.g., due to gravity and pressure), any changes to a coolant level within one IT enclosure may be detected in the reservoir. In which case, a liquid level sensor within the reservoir may control a valve or pump coupled to the coolant source to provide liquid coolant when the senor detects changes in the reservoir's liquid coolant level. Thus, the management unit may manage the distribution of liquid coolant within each of the IT enclosures.

According to one embodiment, a (e.g., distribution and management) cooling system includes one or more IT enclosures, each IT enclosure having one or more pieces of IT equipment that is configured to provide IT services and is at least partially submerged within a liquid coolant, a distribution manifold to which each of the one or more IT enclosures is coupled in parallel to one another, and a management unit that is coupled to the distribution manifold and to a liquid coolant source that is arranged to supply liquid coolant to the management unit that stores the liquid coolant, the management unit is configured to maintain a same level of the liquid coolant in each of the one or more IT enclosures and the liquid coolant stored in the management unit via the distribution manifold.

In one embodiment, the management unit includes a reservoir that is coupled between the distribution manifold and the liquid coolant source, which stores the liquid coolant supplied by the liquid coolant source, either a valve or a pump that is coupled between the reservoir and the liquid coolant source, and a level sensor that is configured to detect a level of the liquid coolant within the reservoir and control the valve or the pump to draw liquid coolant form the liquid coolant source into the reservoir based on the changes to the level. In another embodiment, in response to receiving the liquid coolant from the liquid coolant source, the management unit maintains the same level by supplying the liquid coolant via the distribution manifold to each of the one or more IT enclosures so as to contemporaneously adjust respective liquid coolant levels in the reservoir and in each of the one or more IT enclosures. In some embodiments, the reservoir has a first internal volume that at least partially holds the liquid coolant stored therein and each of the IT enclosures has a second internal volume that at least partially holds the liquid coolant stored contained therein, the second internal volume is greater than the first internal volume.

In one embodiment, the level sensor is a first level sensor that is configured to control the valve by increasing an opening ratio of the valve or control the pump by increasing a pump speed of the pump in response to detecting that the level is equal to or below a first threshold, the management unit further includes a second level sensor and a third level sensor that are configured to detect the level of the liquid coolant within the reservoir, the second level sensor is configured to increase the opening ratio or the pump speed more in response to detecting that the level of the liquid coolant is equal to or less than a second threshold that is below the first threshold, the third level sensor is configured to decrease the opening ratio or the pump speed in response to detecting that the level of the liquid coolant is equal to or greater than a third threshold that is above the first and second thresholds.

In some embodiments, the cooling system further includes, for each IT enclosure of the one or more IT enclosures, a valve that couples a bottom of the IT enclosure to the distribution manifold, each valve is configured to independently control a flow of liquid coolant from the distribution manifold into a respective IT enclosure. In another embodiment, the cooling system further includes a discharging manifold that couples each of the one or more IT enclosures and the liquid coolant source in parallel with one another. In one embodiment, the cooling system further includes, for each of the one or more IT enclosures, a valve that couples a bottom of the IT enclosure to the discharging manifold, and a pump that couples the discharging manifold to the liquid coolant source, the pump is configured to draw liquid coolant contained within the IT enclosure when the valve is in an open position, and supply the drawn liquid coolant to the liquid coolant source. In another embodiment, each valve is a three-way valve that couples a respective IT enclosure to the distribution manifold and the discharging manifold, the open position is a first open position, when the three-way valve is in a second open position the respective IT enclosure receives liquid coolant form the management unit via the distribution manifold. In one embodiment, the management unit is a first management unit and the liquid coolant source is a first liquid coolant source, the cooling system further includes a second management unit that is coupled to the distribution manifold and a second liquid coolant source, both of the first and second management units are configured to maintain the same liquid coolant independently from each other.

According to another embodiment, a data center includes a data center IT room and a cooling system contained within the data center IT room, which is similar to the cooling system as previously described.

In one embodiment, as used herein, “to couple” one component (or element) to another component may refer to “fluidly” coupling the two components so that a fluid (or liquid), such as a cooling liquid or a liquid coolant may flow between the two components. For example, coupling a first tube to a second tube may couple both tubes together such that liquid coolant may flow from the first tube into the second tube (and/or vice a versa).

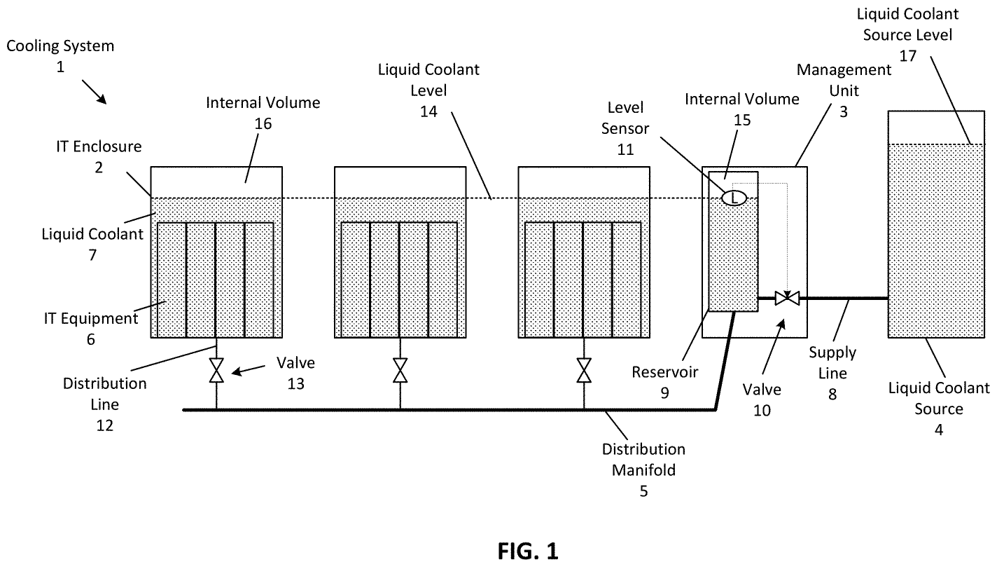

FIG. 1 shows an example of a distribution and management cooling system (or cooling system or system) that includes several IT enclosures coupled to a management unit via a distribution manifold according to one embodiment. Specifically, this figure shows system 1 that is configured to distribute and manage liquid coolant for immersion cooling one or more pieces of IT equipment. The system includes three IT enclosures 2, a management unit 3, a liquid coolant source 4, a distribution manifold (or loop) 5, and three valves 13. In one embodiment, the system may include less or more elements, as described herein. For example, as shown, the cooling system includes three IT enclosures and three respective valves, but could have less elements such as having one IT enclosure coupled (e.g., via a valve 13) to the distribution manifold 5.

In one embodiment, the IT enclosure may be a container (or tank) that may be formed from any type of (e.g., one or more) material(s), such as plastic, metal, etc., and is arranged to hold one or more (e.g., pieces of) IT equipment 6 and (immersion) liquid coolant 7. Specifically, each IT enclosure has one or more pieces of IT equipment that is at least partially submerged within the liquid coolant. For example, as shown, inside each IT enclosure are several (e.g., four) pieces of IT equipment 6 that are (entirely) submerged within the liquid coolant. In another embodiment, one or more IT enclosures may have a different number of pieces of IT equipment stored therein. In some embodiments, an IT enclosure may have any shape and configuration. For example, as illustrated, the enclosure is a square box. In other embodiments, however, the enclosure may be a rectangular or cylindrical box. In addition, as shown, each of the IT enclosures is a same (or similar) size (e.g., width, height, etc.), and each have contained therein a same number of pieces of IT equipment. In another embodiment, one or more of the IT enclosures may be sized differently in order to accommodate more (or less) pieces of IT equipment.

In one embodiment, the IT enclosure may be arranged to add or remove pieces of IT equipment. In which case, the IT enclosure may have a lid (not shown) that is arranged to open in order to gain access into the enclosure (e.g., from the ambient environment). In some embodiments, the IT enclosure may not be arranged to be sealed off (e.g., hermetically sealed) from the ambient environment. For example, when the IT enclosure has a lid and the lid is closed, the IT enclosure may not be sealed such that an interior of the enclosure communicates (e.g., via one or more openings) with the ambient (e.g., outside) environment. In another embodiment, the IT enclosure may not include a lid. In some embodiments, the IT enclosure may include one or more openings into the ambient environment (e.g., an opening on top and/or on the side of the enclosure), such that the ambient environment at least partially communicates with the IT enclosure 2. In some embodiments, these openings may allow the cooling system to maintain a same liquid level, as described herein.

In one embodiment, one or more pieces of IT equipment 6 are configured to provide IT services. Specifically, IT equipment 6 may include a host server (referred to as a host node) coupled to one or more compute servers (also referred to as computing nodes, such as CPU server and GPU server). The host server (having one or more CPUs) typically interfaces with clients over a network (e.g., Internet) to receive a request for a particular service such as storage services (e.g., cloud-based storage services such as backup and/or restoration), executing an application to perform certain operations (e.g., image processing, deep data learning algorithms or modeling, etc., as a part of a software-as-a-service or SaaS platform). In response to the request, the host server distributes the tasks to one or more of the performance computing nodes or compute servers (having one or more GPUs) managed by the host server. In one embodiment, the pieces of IT equipment may perform any type of computing task and/or may be any type of computing device (e.g., a server, a storage device, etc.). In one embodiment, the IT equipment may be edge computing devices. Thus, while the pieces of IT equipment provide the IT services, the equipment generates heat that is transferred into the liquid coolant. More about this process is described herein.

In one embodiment, the liquid coolant source 4 may be any source that is arranged to provide (or supply) liquid coolant. As shown, the liquid coolant source is a container or tank that is holding liquid coolant, and is coupled to the management unit 3 via a supply line 8. In another embodiment, the source may be any type of coolant source, such as a data center cooling water system or an IT liquid cooling water system.

In some embodiments, the liquid coolant 7 may be any type of thermally conductive dielectric liquid. In another embodiment, the coolant may be a non-toxic fluid. In some embodiments, the coolant may be designed for two-phase immersion cooling by having a low boiling point (e.g., below a threshold operating temperature for at least some of the IT equipment housed within the IT enclosures), such that the coolant may turn into a vapor (e.g., once a temperature threshold at which the coolant boils is reached). More about two-phase immersion cooling is described herein.

The distribution manifold 5 is arranged to couple each of the IT enclosures 2 to the management unit 3. Specifically, the IT enclosures and the management unit are coupled in parallel to one another, via the distribution manifold. As shown, each IT enclosure is coupled to the distribution manifold 5 independently (e.g., from one another), via a distribution line 12. In particular, each distribution line 12 is coupled to a bottom (side) of the IT enclosure. In which case, the distribution manifold may be disposed below (one or more of) the IT enclosures and/or may be below the management unit. For example, the distribution manifold may be housed within (or below) a floor (e.g., of a data center in which the cooling system is contained) on top of which each IT enclosure (management unit 3 and/or liquid coolant source 4) sits. In which case, the distribution line may traverse through the raised floor of the data center and couple to a port (not shown) of each IT enclosure and a port (not shown) of the management unit. In some embodiments, the distribution line and a port of the IT enclosure may include connectors that are arranged to removeably couple to one another (e.g., dripless blind mating quick disconnects). As a result, IT enclosures may be added to and/or removed from the distribution manifold 5.

In another embodiment, the distribution manifold 5 may be disposed differently about the IT enclosures. For instance, at least a portion of the distribution manifold may be on a floor on which the IT enclosures are disposed on. In which case, (e.g., one or more of) the distribution line(s) may couple to a bottom of a respective IT enclosures, and/or may couple to the IT enclosures differently. For example, a distribution line may couple to (e.g., a port that is arranged on) a side of the IT enclosure. In another embodiment, one or more distribution lines may couple to respective IT enclosures differently with respect to one another (e.g., one coupled to a bottom of an IT enclosure, while another coupled to a side of another IT enclosure). In one embodiment, the distribution manifold is arranged to distribute (supply) liquid coolant (e.g., from the management unit) to each (or at least one) of the IT enclosures (e.g., once and while the IT enclosures are coupled to the distribution manifold). More about the distribution manifold is described herein.

In one embodiment, for each IT enclosure 2, there is a valve 13 that couples a bottom of the IT enclosure to the distribution manifold 5. Specifically, each valve is coupled between a respective IT enclosure (e.g., and to a respective distribution line 12) and the distribution manifold. Each valve is configured to independently control a flow of liquid coolant from the distribution manifold into a respective IT enclosure. In particular, when the valve is in an open (or at least partially open) position, the IT enclosure may communicate with the distribution manifold in order to allow liquid coolant to flow from the distribution manifold and into the IT enclosure. Conversely, when the valve is in a closed position, the IT enclosure may no longer communicate with the distribution manifold, thereby preventing liquid coolant from flowing into the IT enclosure. In one aspect, each valve may be controlled based on various conditions. For example, when IT equipment 6 is to be removed or maintenance is to be performed on a particular IT enclosure, its respective valve may be put in a closed position in order to not disrupt the liquid level in other IT enclosures. As another example, the valve may allow more (or less) IT enclosures to be coupled to the distribution manifold. For instance, the valve 13 may be removably coupleable to IT enclosures. In which case, an IT enclosure may be coupled to a valve 13 in a closed position (e.g., via a distribution line), and once coupled the valve may be placed in the open position in order to couple the IT enclosure in parallel with other IT enclosures and the management unit, via the distribution manifold. In one embodiment, an IT enclosure is coupled in parallel when liquid coolant is allowed to flow into (and out of) the IT enclosure via the distribution manifold (e.g., when the valve 13 is in the open position).

As shown, the valve 13 is separate from the IT enclosure 2. In another embodiment, the valve may be a part of the IT enclosure. For example, the valve may be coupled (or a part of) a port of the IT enclosure, which is arranged to couple to the distribution manifold via a distribution line 12. In some embodiments, one or more IT enclosures may be coupled to the distribution manifold 5 without one or more valves coupled between.

The management unit 3 is coupled to (and between) the distribution manifold and the liquid coolant source 4 (via a supply line 8), which is arranged to supply liquid coolant to the management unit that stores the liquid coolant. As described herein, the management unit is configured to maintain a same level of liquid coolant in each of the IT enclosures 2 as the liquid coolant stored within the management unit, via the distribution manifold. More about how the management unit maintains the same level is described herein.

As illustrated, the management unit includes a reservoir 9, a level sensor 11 and a valve 10. In one embodiment, each of these components may be housed (or contained) within (e.g., a container of) the management unit. In which case, the valve 10 is coupled between the reservoir and the liquid coolant source 4. In another embodiment, at least some of the components may be separate from the management unit, such as the valve 10 which may be separate from the management unit. In this case, the valve 10 would be coupled between the management unit 3 and the liquid coolant source 4.

In one embodiment, the reservoir is a container (or tank) that is designed to hold (or store) liquid coolant 7. As shown, the reservoir is disposed within the management unit 3. In one embodiment, the reservoir may be partially disposed within the management unit (e.g., with a top portion disposed out of the unit.

As shown, the reservoir 9 is coupled to the distribution manifold 5 and to the liquid coolant source, stores the liquid coolant supplied by the liquid coolant source, and supplies liquid coolant to (e.g., one or more IT enclosures 2 via) the distribution manifold. In one embodiment, the level sensor 11 is configured to sense (detect) a (current) level of the liquid coolant within the reservoir. In some embodiments, the level sensor may be (at least partially) disposed within the (e.g., reservoir of the) management unit 3, and may (at least partially) be arranged to come into contact with liquid coolant. In one embodiment, the sensor may be any type of sensor (e.g., float sensor, conductive sensor, ultrasonic level sensor, etc.), that is configured to detect changes in a level of liquid coolant. In another embodiment, the level sensor may be designed to detect a level of liquid coolant by detecting the presence of liquid, such as an optical level sensor. In this case, a level (or change in the level of) liquid coolant within the management unit may be determined based on the position of the optical sensor (or more specifically the optical detector of the optical sensor) with respect to the management unit.

In some embodiments, the level sensor 11 may be configured to control the valve 10 (e.g., based on (e.g., changes to) the detected level). For instance, the level sensor may be communicatively coupled (e.g., wired and/or wirelessly connected) to the valve 10, which is shown as a dashed line connecting the sensor to the valve. In which case, the level sensor may be configured to control the valve (e.g., by transmitting the produced electrical signal, as a control signal, to control circuitry of the valve, such as an electronic switch) in order to adjust an opening ratio of the valve (e.g., to at least partially open the valve, open the valve all the way, or close the valve all the way). In one embodiment, the level sensor may control the valve 10 to draw liquid coolant from the liquid coolant source into the reservoir based on the changes to the detected level. More about controlling the valve to draw liquid coolant is described herein.

As described herein, one or more of the IT enclosures may not be sealed off from the ambient environment. In another embodiment, the (e.g., reservoir of the) management unit and/or the liquid coolant source may also not be sealed off of from the environment. In which case, the reservoir and/or the liquid coolant source may each include one or more openings that fluidly couple their respective interiors with the ambient environment. For instance, each of these components may include one or more openings that allow fluid (e.g., air) to pass between the interior of the components and the ambient environment. In one embodiment, the openings may be disposed on top of the components (e.g., on top of the reservoir), such that liquid coolant does not spill out.

In one embodiment, each of the IT enclosures, the management unit, and/or the liquid source may be at least partially open to the ambient environment in order for the liquid coolant levels within the IT enclosures and the management unit to be the same. More about the liquid coolant levels being the same is described herein.

In one embodiment, the liquid coolant 7 contained within the cooling system 1 is at a liquid coolant level 14. In particular, as shown, the IT enclosures 2 and the reservoir 9 share the same liquid coolant level 14. This is due to the principle of communicating vessels in which fluid that is shared between (e.g., fluidly) coupled (or communicating) containers settles at a same level in all containers. In this case, the IT enclosures and the reservoir 9 communicate with each other via the distribution manifold (and the distribution lines 12 and valves 13 that are in an open position), and as a result, the liquid coolant 7 that is shared between these components is at one shared level.

As described herein, the management unit maintains a same (e.g., predefined) level of liquid coolant in each of the IT enclosures and in the unit itself. Specifically, the level sensor (e.g., continuously) is used to detect for changes in the level 14 of liquid coolant, which may occur due to various conditions. For example, the level 14 may change based on whether pieces of IT equipment 6 are placed within or removed from IT enclosures. In particular, pieces of IT equipment that are at least partially submerged in each IT enclosure displace the liquid. This displacement reduces an overall available volume within the internal volume 16 of the IT enclosure in which the liquid coolant may be stored, resulting in the liquid coolant level to be higher than if the equipment was not submerged. When a piece of IT equipment is removed from an IT enclosure 2, the liquid coolant level in that particular IT enclosure will drop, due to an increase in the available internal volume. With the reduction in the liquid coolant level, liquid coolant from one or more other IT enclosures and/or the management unit that are coupled in parallel is transferred to the IT enclosure, via the distribution manifold, which results in a reduction in the overall liquid coolant level 14 of the system 1. In one embodiment, the liquid coolant level will settle (reach an equilibrium) across the IT enclosures and the management unit over a period of time, where the new level is lower than the previous level. In another embodiment, the liquid coolant level may drop when IT enclosures are added to the distribution manifold. In which case, when a new IT enclosure is added and a respective valve 13 that is coupled between the newly added IT enclosure and the distribution manifold is opened, the distribution manifold may distribute liquid coolant into the added enclosure from at least some of the other IT enclosures and the management unit.

With a reduction in the liquid coolant level 14, the management unit may compensate for the change in the liquid coolant level by drawing in additional liquid coolant from the liquid coolant source 4 in order to maintain the liquid coolant level from before the drop. In particular, as the liquid coolant level changes (e.g., drops within the reservoir), the level sensor 11 may detect the change and control (e.g., adjust the opening ratio of) the valve 10 in order to receive the additional liquid coolant from the source. In one embodiment, the sensor may adjust the valve in an open position in response to detecting a change, such as a current liquid coolant level being detected as being below a (predefined) threshold level. Liquid coolant may flow from the liquid coolant source 4 into the management unit, due to gravity and pressure of the liquid coolant stored within the source. Specifically, the liquid coolant source level 17 of the liquid coolant within the source 4 is higher (e.g., in a vertical direction) than the liquid coolant level 14 (e.g., by a threshold) within the management unit, which results in the pressure of liquid coolant within the liquid coolant source 4 being greater than the pressure of the liquid coolant within the IT enclosures and/or management unit. This increase in pressure result in the liquid coolant flowing from the source and into the unit. In one embodiment, an adjustment to the opening ratio of the valve may be based on the detected change in the liquid coolant level by the sensor. For instance, as the liquid coolant level drops, the sensor may be arranged to detect a rate at which the level drops and may increase the opening ratio of the valve accordingly (e.g., increasing the opening ratio proportionally with the rate at which the level drops). Thus, the management unit may compensate for the reduction of the liquid coolant level by adjusting the opening ratio of the valve.

In response to the (reservoir of the) management unit receiving the liquid coolant from the liquid coolant source, the management unit maintains the same level (e.g., across at least some of the enclosures and the management unit) by supplying the received liquid coolant via the distribution manifold to each of the IT enclosures so as to contemporaneously adjust respective liquid coolant levels in the reservoir of the unit and in each of the one or more IT enclosures. In particular, the distribution manifold is arranged to automatically balance liquid coolant levels in each of the IT enclosures to a same level (e.g., which may be over a period of time). Thus, liquid coolant is distributed to (at least some of) the IT enclosures as the reservoir receives additional liquid coolant. As a result, the overall liquid coolant level 14 will rise, while the level 17 of the source may lower. In one embodiment, the level sensor may detect the increase in the level of liquid coolant within the reservoir (which may be indicative of the level within each of the IT enclosures as well), and may adjust (e.g., close) the valve 10 once the level sensor detects the liquid coolant level in the reservoir reaches the predefined level threshold. Once the predefined level threshold is reached, the valve 10 may be closed. Once closed, the level of liquid coolant of the IT enclosures and the reservoir would settle to an equilibrium, as described herein. Thus, the management unit is able to efficiently control (e.g., auto-balance) the liquid coolant level in each of the IT enclosures by only monitoring the liquid coolant level within the reservoir of the unit. In some embodiments, the liquid coolant level threshold that is maintained by the management unit may be adjustable.

In one embodiment, the reservoir 9 may be designed to hold less liquid coolant than one or more IT enclosures 2. Specifically, as shown, the reservoir as a (first) internal volume 15 that at least partially holds the liquid coolant 7 stored therein, and each of the IT enclosures 2 has a (second) internal volume 16, where the internal volume of the IT enclosures is greater than the internal volume of the reservoir. In one embodiment, the internal volumes 16 may be an available internal volume in which the IT enclosures may hold liquid coolant, as described herein. As a result of the reservoir having a lower internal volume, the management unit may more precisely monitor the liquid coolant level 14 of the cooling system.

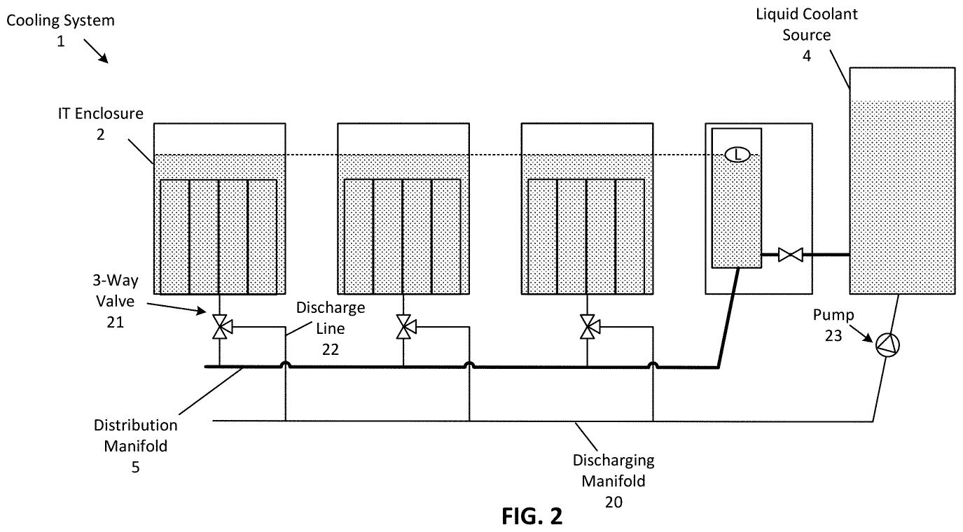

FIG. 2 shows an example of the distribution and management cooling system 1 that includes a discharging manifold 20 according to one embodiment. The discharging manifold 20 couples each of the IT enclosures 2 and the liquid coolant source 4 in parallel with one another, and is arranged to return liquid coolant from one or more IT enclosures (back) into the liquid coolant source. More about how the liquid coolant is returned to the source is described herein.

In one embodiment, the discharging manifold 20 may be coupled to one or more IT enclosures 2 in a similar fashion as the distribution manifold 5, as described herein. For instance, the discharging manifold may be disposed (or housed) within or below a floor on which the IT enclosures (and/or the management unit and/or the source) are mounted, and may be coupled to a bottom of the IT enclosures (to help discharge liquid coolant entirely out of the IT enclosures). Also, as shown, the discharging manifold is coupled to a bottom of the liquid coolant source 4. In another embodiment, the manifold 20 may be coupled differently to the source, such as being coupled to a top (side) of the source 4.

The system 1 includes, for each IT enclosure, a valve 21 that couples (e.g., a bottom of) the IT enclosure to the discharging manifold, via a discharge line 22. In particular, the valve 21 is a three-way (or “3-way”) valve that couples a respective IT enclosure to the distribution manifold 5 and the discharging manifold 20. This 3-way valve is arranged to allow individual IT enclosures to communicate with either the distribution manifold or the discharging manifold at a different time, based on the position of the valve. For example, when the valve 21 is in a first open position, a respective IT enclosure may be arranged to communicate with the liquid coolant source and supply liquid coolant stored within the IT enclosure to the source, via the discharging manifold 20. When the valve 21 is in a second open position, the IT enclosure may be arranged to communicate with the management unit 3 and receive liquid coolant from the unit, via the distribution manifold 3. Thus, the IT enclosure may be arranged to communicate with either the management unit or the liquid coolant source, based on the open position of the 3-way valve. In some embodiments, the 3-way valve may have a (third position) closed position in which a respective IT enclosure is not communicating with the distribution manifold or the discharging manifold. Such a position may allow IT enclosures to be added into the cooling system. Thus, the three-way valves enable IT enclosures to be efficiently added/removed in parallel with the distribution and discharging manifolds, and for allows for more efficient liquid coolant management.

In one embodiment, the system may include multiple valves coupled to one or more IT enclosures. For instance, rather than (or in addition to) having a three-way valve 21, the system may include at least two two-way valves, similar to valve 13, as shown in FIG. 1. In which case, a first two-way valve may couple an IT enclosure to the distribution manifold 5 and a second two-way valve may couple the IT enclosure to the discharging manifold 20.

The system 1 also includes a (liquid) pump 23 that couples the discharging manifold 20 to the liquid coolant source 4, where the pump is arranged to draw liquid coolant contained within one or more IT enclosures, (e.g., when the valve 21 is in the first open position) and supply the drawn liquid coolant to the liquid coolant source. In one embodiment, the pump may be activated in response to one or more 3-way valves being (or positioned) in the first open position in order to pull coolant out of the IT enclosure. A pump speed of the pump may be defined based on a number of valves are in the first open position. For example, the pump speed may be proportional to the number of valves that are in the first open position, such that as the number increases, the pump speed may be increased in order to increase the flow rate at which the source receives liquid coolant. In another embodiment, the pump may be deactivated when none of the valves 21 are in the first open position.

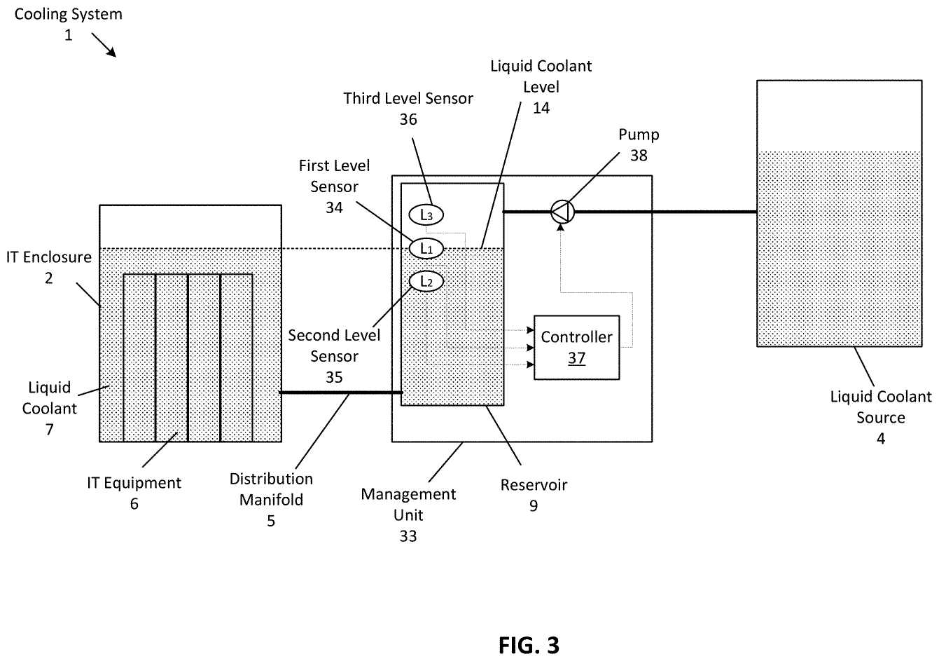

FIG. 3 shows an example of the distribution and management cooling system 1 according to another embodiment. As shown, the management unit 33 includes three level sensors 34-36, the reservoir 9, a controller 37, and a pump 38. Similar to management unit 3 of FIG. 1, this unit 33 is coupled between the distribution manifold 5 and the liquid coolant source. As shown, the pump 38 is coupled between the reservoir 9 and the liquid coolant source 4, in lieu of the valve 10, as shown in FIG. 1. The pump 38 is configured to draw (e.g., while active) liquid coolant 7 from the source 4 and provide the drawn liquid coolant into the reservoir 9. While the pump is not active, however, no liquid coolant may be flowing from the liquid coolant source 4 into the management unit. In one embodiment, the configuration of one or more components of the cooling system 1 in this figure may differ than that of the system configuration shown in FIG. 1. For example, by using a pump to draw in the liquid coolant, the system no longer requires gravity to assist in drawing liquid coolant from the liquid coolant source. The liquid coolant level of coolant contained within the source does not need to be higher than the liquid coolant level 14 of the IT enclosure 2 and the management unit 3 in order for liquid coolant to flow from the source and into the reservoir. More about drawing the liquid coolant from the liquid coolant source is described herein.

In this figure, the management unit 33 includes three level sensors 34-36, where each sensor is designed to detect the level of liquid coolant within the reservoir 9, and is configured to control the pump 38 based upon one or more detected liquid coolant levels by one or more of the sensors. Having multiple level sensors may allow the management unit to accurately and efficiently control a pump speed of the pump 38 in order to compensate for any changes in the liquid coolant level. For example, auto-balancing the liquid coolant level throughout multiple IT enclosures via the distribution manifold may take time. During which time, the liquid coolant level may continue if the pump does not provide a sufficient amount of liquid coolant to compensate for the drop. As a result, multiple sensors may be used to monitor the fluctuating level, and may be configured to adjust the pump speed in order to reduce the amount of time during which the liquid coolant is auto-balanced by the system (e.g., where the liquid coolant reaches an equilibrium level within the system). As an example, the first level sensor 34, which may be similar to sensor 11 of FIG. 1, may increase the pump speed of the pump upon detecting that the level 14 is equal to or less than a (first) threshold, while the second level sensor 35 may further increase the pump speed upon detecting that the level 14 is equal to or less than a (second) threshold. In particular, the pump speed may be increased in order to compensate for the drop in liquid coolant within the reservoir. Conversely, first level sensor 34 may decrease the pump speed upon detecting that the level is greater than the first threshold. In addition, the third level sensor 36 may be configured to decrease the pump speed of the pump in response to detecting that the level is equal to or greater than a (third) threshold, which may be higher than the first and second thresholds. Thus, in this example, the system may further decrease the pump speed as the liquid coolant level rises. In one embodiment, the management unit may use the third level sensor to ensure that the system 1 does not draw in too much liquid coolant from the source 4. In which case, the system may deactivate the pump once the third level sensor 36 detects that the level is equal or greater than the third threshold. More about these sensors is described herein.

The controller 37 may be a special-purpose processor such as an application-specific integrated circuit (ASIC), a general purpose microprocessor, a field-programmable gate array (FPGA), a digital signal controller, or a set of hardware logic structures (e.g., filters, arithmetic logic units, and dedicated state machines). In one embodiment, the controller may be a circuit with a combination of analog elements (e.g., resistors, capacitors, inductors, etc.) and/or digital elements (e.g., logic-based elements, such as transistors, etc.). The controller may also include memory. In one embodiment, the controller may be a part (or integrated) into the management unit, as shown. In another embodiment, the controller may be one of the pieces of IT equipment 6 that is at least partially submerged within the liquid coolant 7. In another embodiment, the controller may be a separate electronic device that is communicatively coupled with the management unit 3. In yet another embodiment, the controller may be an optional component. In which case, the management unit may not include the controller, and in this case the one or more level sensors may (e.g., be communicatively coupled with the pump and) control the pump, as described herein.

In one embodiment, the controller 37 is communicatively coupled (e.g., wired and/or wirelessly connected) to the pump 38 and to the level sensors 34-36. Specifically, the controller is configured to receive (e.g., electrical) signals from the sensors that may indicate a detected liquid coolant level within the reservoir, and may be configured to control the pump 38 (e.g., by transmitting a control signal to control circuitry of the pump, such as an electronic switch) in order to control the pump based on one or more detected liquid coolant levels. For example, the controller may activate the pump in response to determining that the liquid coolant level 14 drops below a threshold based on a detected level by the first level sensor 34. Conversely, the controller may deactivate the pump in response to determining that the liquid coolant level is above the threshold. This may ensure that the pump is only activated upon the level being detected below the threshold.

In another embodiment, the controller may be configured to perform one or more operations described herein for adjusting the pump speed of the pump based on the detected levels by one or more sensors. Specifically, the controller may increase or decrease a pump speed of the pump based on the detected levels, as described herein. For example, the controller may determine the current liquid coolant level 14 based on one or more signals from one or more sensors 34-36, and may adjust the pump speed based on whether the currently detected level is greater than (and/or less than) one or more thresholds in order for the reservoir to (e.g., approximately) maintain a (e.g., constant, predefined) liquid coolant level. In one embodiment, the controller may be reconfigurable, such that the predefined liquid coolant level may be adjustable. This may allow the predefined level that is maintained by the management unit to be configured based on various conditions (e.g., the number and size of IT equipment, the size of the IT enclosure with respect to the size of the IT equipment, etc.).

In some embodiments, the pump speed may be adjusted based on a rate at which the level 14 changes within the reservoir. For instance, the controller 37 may monitor liquid coolant levels detected by one or more of the level sensors 34-36, and adjust the pump speed based on changes to the monitored levels. These operations may be performed based on the type of level sensors that are used. When the level sensors are “point” sensors that indicate whether there is a presence of liquid at a particular point (e.g., along the sensor), the controller may adjust the pump speed based on a period of time that the presence (or absence) of liquid is detected by two or more sensors. For example, the controller may receive a first signal from the first level sensor 34 indicating that there is an absence of liquid, which may result in the liquid level dropping below the sensor. After a period of time, the second level sensor 35 may transmit a (e.g., similar) signal indicating the absence of liquid. The controller may determine the rate that the level is dropping based on the period of time, and adjust the pump speed to compensate.

In one embodiment, the controller 37 may be configured to control the pump 38 using one level sensor, such as sensor 34. For example, upon receiving a signal from the sensor 34 that indicates a current level, the controller may compare the current level to the predefined level, and based on the difference adjust the pump 38.

As shown in this figure, the pump 38 may be utilized for maintaining the liquid coolant level. As described herein, in lieu of (and/or in addition to) the pump, the system may include a valve, such as valve 10 in management unit 3 shown in FIG. 1, for maintaining the level. In which case, the valve may be controlled similarly as the pump 38 to maintain the level. Specifically, the controller 37 may be configured to control a valve based on signals from one or more of the level sensors. For example, the controller may at least partially open the valve upon determining that a detected level of the first level sensor 34 is below the first threshold. In addition, the controller may open (e.g., increase an opening ratio) of the valve more upon detecting that the level of the liquid coolant has dropped below a second threshold (based on signals from the second level sensor 35). In which case, the management unit 3 may include one or more of the components of unit 33 for managing the distribution of liquid coolant, such as one or more level sensors and a controller that is communicatively coupled to the sensors and valve, as described here.

As described thus far, the cooling system 1 may include one or more valves, such as valve 13 in FIG. 1, for controlling whether respective IT enclosures communicate with the management unit via the distribution manifold for receiving liquid coolant, and/or one or more pumps, such as pump 23 in FIG. 2, for drawing liquid coolant (through the discharging manifold) from one or more IT enclosures 2 and supplying the liquid coolant into the liquid coolant source. In one embodiment, the valves and/or pump may be controlled by the management unit. For example, the controller 37 may be communicatively coupled with the valves/pump, and may be configured to control these elements. In particular, the controller may be configured to receive user commands for closing one or more valves that couple one or more IT enclosures to the distribution manifold (and/or discharging manifold).

As described herein, the IT enclosure provides two-phase immersion cooling for the pieces of IT equipment 6 that are contained within the enclosures. In one embodiment, the system 1 may include a condenser (not shown) that is configured to provide the two-phase immersion cooling. Specifically, as the IT equipment 6 are active (e.g., performing computational operations), heat produced by the equipment is transferred into the liquid coolant 7. This transfer of heat warms, the coolant, causing the coolant to (at least partially) boil and produce vapor. The condenser may be fluidly coupled to the IT enclosure (e.g., coupled to a port that is on top or near the top of the enclosure), and may be arranged to receive (at least a portion of) the produced vapor. The condenser may be a heat exchanger that is configured to condense the vapor into a cool (condensed) liquid. For example, the condenser may be a two-phase liquid-to-liquid heat exchanger that is arranged to transfer heat within the vapor into a liquid coolant that flows through the heat exchanger (e.g., which may be separate coolant from the liquid coolant 7), which causes the vapor to produce condensate. In one embodiment, this separate liquid coolant may be received from a coolant source (e.g., a data center liquid coolant system). In one embodiment, the condenser may have a return port that is coupled to the IT enclosure, and is arranged to return condensate back into the IT enclosure. In another embodiment, the condensate may be supplied back to the liquid coolant source 4 and/or the (e.g., reservoir of the) management unit.

In one embodiment, the condenser may be disposed outside of the IT enclosure (e.g., sitting on top of the enclosure or a separate standalone unit), and may be fluidly coupled to the IT enclosure, as described herein. In another embodiment, the condenser may be integrated within (e.g., above the liquid coolant 7) the IT enclosure. In which case, the condenser may be coupled (e.g., via the IT enclosure) to the separate liquid coolant source in order to condense vapor within the IT enclosure back into condensate, which is returned back into the internal volume of the IT enclosure. In another embodiment, the condenser may be only partially disposed within the IT enclosure, thereby allowing at least a portion of the condenser to be exposed to the ambient environment.

In some embodiments, each IT enclosure (such as the enclosures shown in FIG. 1) may have (or be coupled to) an individual condenser that condenses vapor produced within its respective IT enclosure. In another embodiment, one or more IT enclosures of the cooling system 1 may be coupled to a shared condenser, which is arranged to condense vapor from the one or more enclosures. In which case, the shared condenser may return a portion of condensate to each IT enclosure and/or may return the condensate to the liquid coolant source 4 and/or the management unit, as described herein.

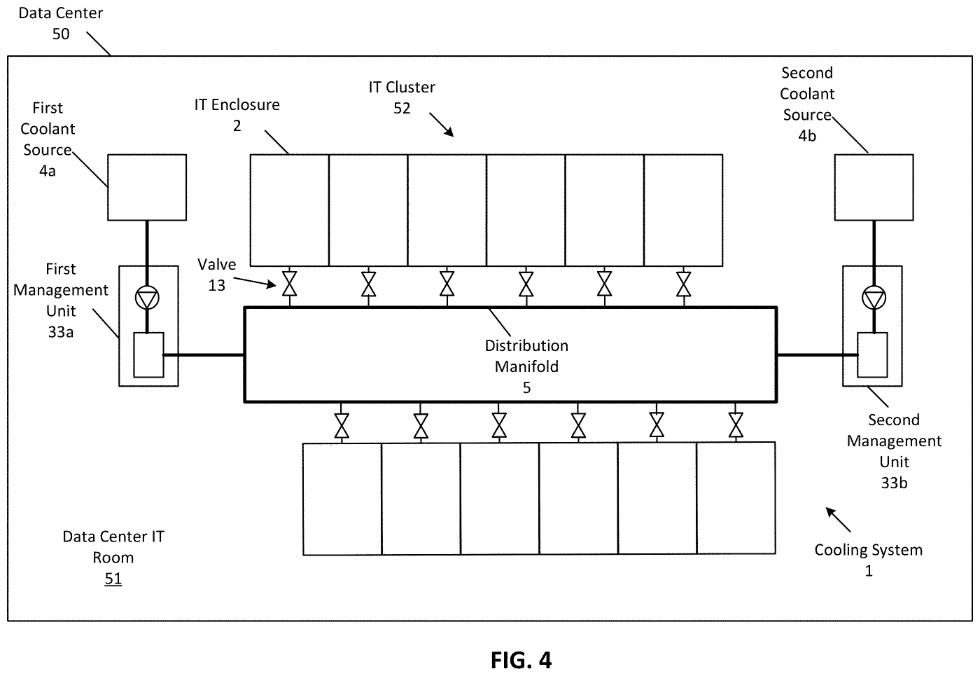

FIG. 4 shows an IT cluster 52 in a data center 50 that includes an example of the distribution and management cooling system with several management units according one embodiment. The data center 50 includes a data center IT room 51 that includes (e.g., contained therein) the cooling system 1 that has an IT cluster 52 of several IT enclosures. Specifically, the IT cluster includes two parallel rows of IT enclosures, each row having six IT enclosures. In one embodiment, the clusters of IT enclosures may include any number of IT enclosures and may be positioned within the data center in any configuration. The cooling system 1 also has several management units that are configured to maintain coolant levels throughout one or more IT enclosures of the IT cluster. Between the two rows of IT enclosures is the distribution manifold that is coupled (e.g., via separate valves, such as valve 13 of FIG. 1) to each IT enclosure. On the left side of the IT enclosures is a first management unit 33a that is coupled between the distribution manifold 5 and a first coolant source 4a, and on a right side of the IT enclosures is a second management unit 33b that is coupled between the distribution manifold and a second coolant source 4b. As shown, both of the management units are similar to the management unit 33 shown in FIG. 3 (e.g., both having a pump coupled to a reservoir).

In one embodiment, both of the management units 33a and 33b may be configured to maintain a same level of liquid coolant independently from each other. Specifically, both units may perform at least some of the operations described herein to manage the distribution of liquid coolant throughout the IT enclosures. In another embodiment, both management units may operate in sync. In which case, one of the (e.g., controllers within one of the) units may be configured to receive signals from one or more level sensors within one or both units, and may be configured to control one or more liquid pumps within the units based on the received signals, as described herein.

In another embodiment, one of the management units may be a redundant unit. In which case, the first management unit 33a may be used by the cooling system 1 for distributing liquid coolant. If the first management unit becomes inoperable (e.g., while a service is being performed upon the unit), the second management unit may be activated for managing the distribution of liquid coolant. In some embodiments, the management units 33a and 33b may be coupled to a same liquid coolant source (e.g., 4a), rather than being coupled to individual sources.

In one embodiment, one or both of the management units may be similar (or the same) as management unit 3 (e.g., illustrated in FIG. 1). For example, the management units may include one or more valves (e.g. valve 10) that are coupled to and disposed between a reservoir of the management unit and the liquid coolant source in lieu of (or in addition to) the pumps of units 33a and/or 33b for managing the distribution of liquid coolant from the source. Thus, the system may manage liquid coolant distribution using several management units that include one or more valves. In some embodiments, the system 1 may include a combination of management units 3 and 33 for distributing liquid coolant throughout the distribution manifold. Thus, in one embodiment, the system may include management units 3 and 33 that are both coupled to the distribution manifold.

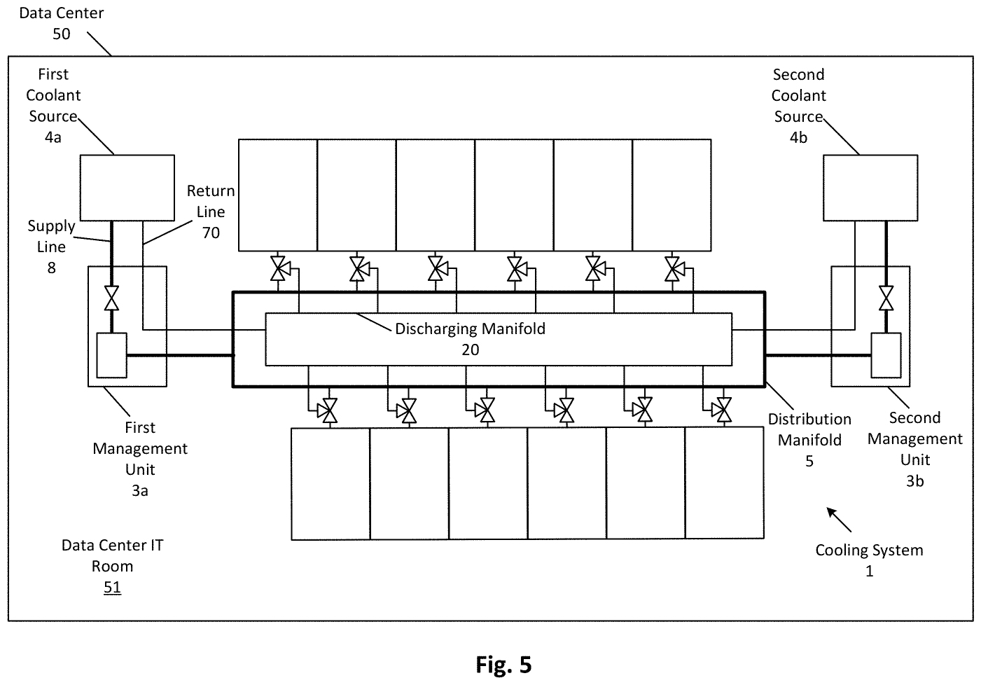

FIG. 5 shows the data center that includes another example of the distribution and management cooling system 1 according to one embodiment. This figure shows the cooling system, as shown in FIG. 2, which includes the distribution manifold 5 and the discharging manifold 20. Specifically, as shown, both manifolds are coupled to and disposed between the two rows of IT enclosures, where each manifold is coupled to each IT enclosure 2 via a 3-way valve, such as valve 21 illustrated in FIG. 2. In this example, both the discharging and distribution manifolds are coupled to each coolant source 4a and 4b, via the management units 3a and 3b, respectively. For example, the first management unit 3a is coupled between the discharging manifold 20 and the first coolant source, via a return line 70. In particular, the return line couples to an internal line within the management unit, which couples to the discharging manifold. In another embodiment, the discharging manifold may be coupled to one or more of the coolant sources, as shown in FIG. 2.

Although not shown, the cooling system 1 may include one or more pumps 23 that are arranged to draw liquid coolant from the discharging manifold and provide the liquid coolant to one or both of the coolant sources. In some embodiments, these pumps may be disposed within the management units. In another embodiment, one or more of the management units in this figure may be similar to management unit 33, whereby the management unit controls the level of liquid coolant within the system using one or more pumps (e.g., pump 38 of FIG. 3).

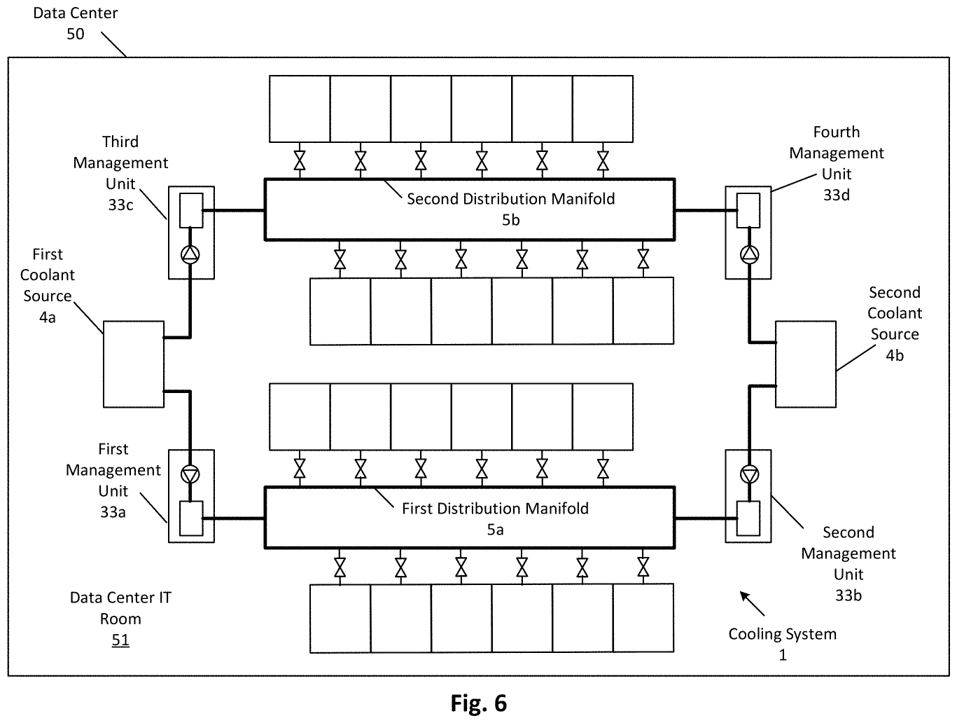

FIG. 6 shows the data center that includes another example of the distribution and management cooling system according to another embodiment. This figure illustrates the cooling system 1 within a data center IT room 51 that is providing immersion cooling through several distribution manifolds 5a and 5b. In particular, there are four rows of IT enclosures, where the first distribution manifold 5a is coupled between the bottom two rows and the second distribution manifold 5b is coupled between the top two rows. Also, there are two management units for each distribution manifold. In particular, a first management unit 33a and a second management unit 33b are coupled to the first distribution manifold, and a third management unit 33c and a fourth management unit 33d are coupled to the second distribution manifold.

Several of the management units share a same coolant source. In particular, the first and third management units are coupled to the first coolant source 4a, and the second and fourth management units are coupled to the second coolant source 4b. By having multiple management units (removeably) coupleable to a same coolant source, the cooling system is scalable and expandable for immersion cooling needs.

In one embodiment, the cooling system in this figure may include the discharging similarly coupled to one or more management units. For example, the system may include two discharging manifolds, one for each pair of rows of IT enclosures.

As previously explained, an embodiment of the disclosure may be (or include) a non-transitory machine-readable medium (such as microelectronic memory) having stored thereon instructions, which program one or more data processing components (generically referred to here as a “processor”) to perform liquid coolant management and distribution operations, as described herein. In other embodiments, some of these operations might be performed by specific hardware components that contain hardwired logic. Those operations might alternatively be performed by any combination of programmed data processing components and fixed hardwired circuit components.

In the foregoing specification, embodiments of the disclosure have been described with reference to specific exemplary embodiments thereof. It will be evident that various modifications may be made thereto without departing from the broader spirit and scope of the disclosure as set forth in the following claims. The specification and drawings are, accordingly, to be regarded in an illustrative sense rather than a restrictive sense.

While certain embodiments have been described and shown in the accompanying drawings, it is to be understood that such embodiments are merely illustrative of and not restrictive on the broad disclosure, and that the disclosure is not limited to the specific constructions and arrangements shown and described, since various other modifications may occur to those of ordinary skill in the art. The description is thus to be regarded as illustrative instead of limiting.

In some embodiments, this disclosure may include the language, for example, “at least one of [element A] and [element B].” This language may refer to one or more of the elements. For example, “at least one of A and B” may refer to “A,” “B,” or “A and B.” Specifically, “at least one of A and B” may refer to “at least one of A and at least one of B,” or “at least of either A or B.” In some embodiments, this disclosure may include the language, for example, “[element A], [element B], and/or [element C].” This language may refer to either of the elements or any combination thereof. For instance, “A, B, and/or C” may refer to “A,” “B,” “C,” “A and B,” “A and C,” “B and C,” or “A, B, and C.”

What is claimed is:

1. A cooling system comprising:
one or more information technology (IT) enclosures, each IT enclosure having one or more pieces of IT equipment that is configured to provide IT services and is at least partially submerged within a liquid coolant;
a distribution manifold to which each of the one or more IT enclosures is coupled in parallel to one another; and
a management unit that is coupled to the distribution manifold and to a liquid coolant source that is arranged to supply liquid coolant to the management unit that stores the liquid coolant, the management unit is configured to maintain a same level of the liquid coolant in each of the one or more IT enclosures and the liquid coolant stored in the management unit via the distribution manifold.

2. The cooling system of claim 1, wherein the management unit comprises
a reservoir that is coupled between the distribution manifold and the liquid coolant source, which stores the liquid coolant supplied by the liquid coolant source;
either a valve or a pump that is coupled between the reservoir and the liquid coolant source; and
a level sensor that is configured to detect a level of the liquid coolant within the reservoir and control the valve or the pump to draw liquid coolant from the liquid coolant source into the reservoir based on the changes to the level.

3. The cooling system of claim 2, wherein, in response to receiving the liquid coolant from the liquid coolant source, the management unit maintains the same level by supplying the liquid coolant via the distribution manifold to each of the one or more IT enclosures so as to contemporaneously adjust respective liquid coolant levels in the reservoir and in each of the one or more IT enclosures.

4. The cooling system of claim 2, wherein the reservoir has a first internal volume that at least partially holds the liquid coolant stored therein and each of the IT enclosures has a second internal volume that at least partially holds the liquid coolant stored contained therein, the second internal volume is greater than the first internal volume.

5. The cooling system of claim 2, wherein the level sensor is a first level sensor that is configured to control the valve by increasing an opening ratio of the valve or control the pump by increasing a pump speed of the pump in response to detecting that the level is equal to or below a first threshold, wherein the management unit further comprises
a second level sensor and a third level sensor that are configured to detect the level of the liquid coolant within the reservoir, the second level sensor is configured to further increase the opening ratio or the pump speed in response to detecting that the level of the liquid coolant is equal to or less than a second threshold that is below the first threshold, the third level sensor is configured to decrease the opening ratio or the pump speed in response to detecting that the level of the liquid coolant is equal to or greater than a third threshold that is above the first and second thresholds.

6. The cooling system of claim 1 further comprises, for each IT enclosure of the one or more IT enclosures, a valve that couples a bottom of the IT enclosure to the distribution manifold, each valve is configured to independently control a flow of liquid coolant from the distribution manifold into a respective IT enclosure.

7. The cooling system of claim 1 further comprising a discharging manifold that couples each of the one or more IT enclosures and the liquid coolant source in parallel with one another.

8. The cooling system of claim 7 further comprises:
for each of the one or more IT enclosures, a valve that couples a bottom of the IT enclosure to the discharging manifold; and
a pump that couples the discharging manifold to the liquid coolant source, the pump is configured to draw liquid coolant contained within the IT enclosure when the valve is in an open position, and supply the drawn liquid coolant to the liquid coolant source.

9. The cooling system of claim 8, wherein each valve is a three-way valve that couples a respective IT enclosure to the distribution manifold and the discharging manifold, wherein the open position is a first open position, wherein when the three-way valve is in a second open position the respective IT enclosure receives liquid coolant from the management unit via the distribution manifold.

10. The cooling system of claim 1, wherein the management unit is a first management unit and the liquid coolant source is a first liquid coolant source, wherein the cooling system further comprises a second management unit that is coupled to the distribution manifold and to a second liquid coolant source, both of the first and second management units are configured to maintain the same level of liquid coolant independently from each other.

11. A data center comprising:
a data center information technology (IT) room; and
a cooling system contained within the data center IT room that includes:
one or more IT enclosures that each have one or more pieces of IT equipment that is configured to perform IT services and is at least partially submerged within a liquid coolant;
a distribution manifold to which each of the one or more IT enclosures is coupled in parallel to one another; and
a management unit that is coupled to the distribution manifold and to a liquid coolant source that is arranged to supply liquid coolant to the management unit that stores the liquid coolant, the management unit is configured to maintain a same fluid level of the liquid coolant in each of the one or more IT enclosures and of the liquid coolant stored in the management unit via the distribution manifold.

12. The data center of claim 11, wherein the management unit comprises
a reservoir that is coupled between the distribution manifold and the liquid coolant source, which stores the liquid coolant supplied by the liquid coolant source;
either a valve or a pump that is coupled between the reservoir and the liquid coolant source; and
a level sensor that is configured to detect a level of the liquid coolant within the reservoir and control the valve or the pump to draw liquid coolant from the liquid coolant source into the reservoir based on the changes to the level.

13. The data center of claim 12, wherein, in response to receiving the liquid coolant from the liquid coolant source, the management unit maintains the same level by supplying the liquid coolant via the distribution manifold to each of the one or more IT enclosures so as to contemporaneously adjust respective liquid coolant levels in the reservoir and in each of the one or more IT enclosures.

14. The data center of claim 12, wherein the reservoir has a first internal volume that at least partially holds the liquid coolant stored therein and each of the IT enclosures has a second internal volume that at least partially holds the liquid coolant stored contained therein, the second internal volume is greater than the first internal volume.

15. The data center of claim 12, wherein the level sensor is a first level sensor that is configured to control the valve by increasing an opening ratio of the valve or control the pump by increasing a pump speed of the pump in response to detecting that the level is equal to or below a first threshold, wherein the management unit further comprises
a second level sensor and a third level sensor that are configured to detect the level of the liquid coolant within the reservoir, the second level sensor is configured to further increase the opening ratio or the pump speed in response to detecting that the level of the liquid coolant is equal to or less than a second threshold that is below the first threshold, the third level sensor is configured to decrease the opening ratio or the pump speed in response to detecting that the level of the liquid coolant is equal to or greater than a third threshold that is above the first and second thresholds.

16. The data center of claim 11, wherein the cooling system further comprises, for each IT enclosure of the one or more IT enclosures, a valve that couples a bottom of the IT enclosure to the distribution manifold, each valve is configured to independently control a flow of liquid coolant from the distribution manifold into a respective IT enclosure.

17. The data center of claim 11, wherein the cooling system further comprises a discharging manifold that couples each of the one or more IT enclosures and the liquid coolant source in parallel with one another.

18. The data center of claim 17, wherein the cooling system further comprises:
for each of the one or more IT enclosures, a valve that couples a bottom of the IT enclosure to the discharging manifold; and
a pump that couples the discharging manifold to the liquid coolant source, the pump is configured to draw liquid coolant contained within the IT enclosure when the valve is in an open position, and supply the drawn liquid coolant to the liquid coolant source.

19. The data center of claim 18, wherein each valve is a three-way valve that couples a respective IT enclosure to the distribution manifold and the discharging manifold, wherein the open position is a first open position, wherein when the three-way valve is in a second open position the respective IT enclosure receives liquid coolant from the management unit via the distribution manifold.

20. The data center of claim 11, wherein the management unit is a first management unit and the liquid coolant source is a first liquid coolant source, wherein the cooling system further comprises a second management unit that is coupled to the distribution manifold and to a second liquid coolant source, both of the first and second management units is are configured to maintain the same level of liquid coolant independently from each other.
